(19) United States
(12) Patent Application Publication
(10) Pub. No.: US 2025/0267797 A1
(43) Pub. Date: Aug. 21, 2025

(54) PATTERN-PRINTED THICK FILM ROLL AND METHOD FOR MANUFACTURING PATTERN-PRINTED THICK FILM ROLL

(71) Applicant: NISSHA CO.,LTD., Kyoto (JP)

(72) Inventor: Hideaki NADA, Kyoto (JP)

(73) Assignee: NISSHA CO.,LTD., Kyoto (JP)

(21) Appl. No.: 18/580,824

(22) PCT Filed: Jun. 9, 2022
(86) PCT No.: PCT/JP2022/023217

§ 371 Date: Sep. 26, 2024

(30) Foreign Application Priority Data
Jul. 21, 2021 (JP) 2021-120273

(51) Int. Cl. H05K 3/12; H05K 3/00; H05K 3/22; H05K 3/28

(52) U.S. Cl. CPC H05K 3/1225; H05K 3/005; H05K 3/0079; H05K 3/227; H05K 3/28; H05K 2203/0139; H05K 2203/0264; H05K 2203/17

(57) ABSTRACT

A pattern-printed thick film roll and a method for manufacturing the pattern-printed thick film roll can reduce defective products and material loss. The method for manufacturing a pattern-printed thick film roll (5) includes preparing a laminate of a printing substrate film (1) being elongated and comprising resin and a masking film (2) being elongated, comprising resin, having multiple through-holes (2a), and being bonded to a surface of the printing substrate film (1), filling, with ink (32), the through-holes (2a) in the masking film (2) in the laminate of the printing substrate film (1) and the masking film (2) to form an ink film (31), drying the ink film (31) to form a pattern-printed thick film layer (3) having a thickness of 10 to 400 μm, and winding a stack (4) including the printing substrate film (1), the masking film (2), and the pattern-printed thick film layer (3) into a roll.

### TECHNICAL FIELD

The present invention relates to a pattern-printed thick film roll and a method for manufacturing the pattern-printed thick film roll that can reduce defective products and material loss.

### BACKGROUND

Electrical products including electrical component sheets such as flexible sheet touch sensors have been manufactured. A known technique for manufacturing a component module including a sheet touch sensor described in, for example, Patent Literature 1 includes integrating the touch sensor with a thermoplastic resin molded product by injection molding to form the component module including the touch sensor.

The component module described in, for example, Patent Literature 1 or Patent Literature 2 includes an electrical component sheet including a functional layer functioning as, for example, a touch-sensor circuit formed on a substrate film. The sheet is formed in conformance with the shape of the back surface of the molded product to receive, for example, a flexible printed circuit board. The sheet is then integrated with the molded product by insert molding with a mold.

A method for manufacturing such an electrical component sheet described in Patent Literature 1 or Patent Literature 2 includes, for example, screen printing to form a functional layer on a substrate film, or in particular, a layer on which conductive ink is printed by thick film printing.

### CITATION LIST

### Patent Literature

Patent Literature 1: Japanese Unexamined Patent Application Publication No. 2014-35806
Patent Literature 2: Japanese Unexamined Patent Application Publication No. 2019-028928

### BRIEF SUMMARY

### Technical Problem

The thick film printing including screen printing has the issues described below.

As shown in FIG. 14, in screen printing, a screen plate 100 is placed on a substrate film 105. The screen plate 100 includes a screen mesh 100a partially covered with an emulsion 100b and openings 100c not covered with the emulsion 100b. The openings 100c correspond to a print pattern 104. Ink 32 is spread uniformly over the screen plate 100 with a doctor blade (not shown) to fill holes in the screen mesh 100a in the openings 100c. The ink 32 is sequentially pressed against the substrate film 105 from the edge of the screen plate 100 with a squeegee 33. When the screen plate 100 pressed with the squeegee 33 is in contact with the substrate film 105 and is then separate from the substrate film 105, the ink 32 filling the holes in the screen mesh 100a in the openings 100c is transferred to the substrate film 105. In other words, although a portion of the screen plate 100 pressed with the squeegee 33 alone bends to be in contact with the substrate film 105, no object prevents the ink 32 from flowing to an area adjacent to the contact portion. The screen mesh 100a is also located inside the openings 100c corresponding to the print pattern 104. The print pattern 104 in a pattern-printed thick film layer may thus have blotting or misalignment of the ink 32.

In drying the ink film, the substrate film 105 may deform as the ink film shrinks.

The screen plate 100 including a frame 101 obstructs the movement of the squeegee 33, thus forming an unprintable area 102 and causing material loss.

The substrate film including the pattern-printed thick film layer also has an issue when being wound into a roll.

More specifically, the substrate film has protruding areas including the pattern-printed thick film layer and non-protruding areas including no pattern-printed thick film layer. Thus, the shapes of the protruding areas with the pattern-printed thick film layer are transferred to and remain on the overlaid substrate film being wound.

The protruding areas with the pattern-printed thick film layer receive a shear force. The pattern-printed thick film layer is thus more likely to be peeled off or damaged.

The roll with protruding areas and non-protruding areas in the width direction may not easily allow tension control for winding under a tension applied uniformly in the width direction of the roll.

One or more aspects of the present invention are directed to a pattern-printed thick film roll and a method for manufacturing the pattern-printed thick film roll that can reduce defective products and material loss.

### Solution to Problem

In response to the above issue, aspects of the present invention are described below. Any of these aspects may be combined as appropriate.

A method for manufacturing a pattern-printed thick film roll according to one or more aspects of the present invention includes preparing a laminate of a printing substrate film being elongated and comprising resin and a masking film being elongated, comprising resin, having a plurality of through-holes, and being bonded to a surface of the printing substrate film, filling, with ink, the plurality of through-holes in the masking film in the laminate of the printing substrate film and the masking film to form an ink film, drying the ink film to form a pattern-printed thick film layer having a thickness of 10 to 400 μm, and winding a stack including the printing substrate film, the masking film, and the pattern-printed thick film layer into a roll.

The pattern-printed thick film roll obtained with this method is the stack being wound into a roll. The stack includes the elongated resin printing substrate film, the elongated resin masking film, and the pattern-printed thick film layer. The masking film is bonded to the surface of the printing substrate film. The masking film has the plurality of through-holes.

The pattern-printed thick film layer fills the through-holes in the masking film. The pattern-printed thick film layer has a thickness of 10 to 400 μm.

In the above structure, the masking film is used in place of a screen plate to form the pattern-printed thick film layer. The masking film and the printing substrate film have no gaps between them and hold no screen mesh between them, thus allowing the pattern-printed thick-film layer with less blotting or less misalignment of the ink. The printing substrate film and the masking film may receive shrinkage stress generated in drying the ink film. However, the ink film in the through-holes in the masking film reduces shrinkage of the substrate. Additionally, the masking film, unlike the screen plate, includes no frame, thus forming no unprintable area and reducing material loss.

Winding is performed with the masking film having the through-holes filled with the pattern-printed thick film layer. This forms no protruding areas including the pattern-printed thick film layer and non-protruding areas including no pattern-printed thick film layer. Thus, the shapes of the protruding areas with the pattern-printed thick film layer avoid being transferred to the overlaid printing substrate film being wound. The protruding areas with the pattern-printed thick film layer receive no shear force. The pattern-printed thick film layer can thus avoid being peeled off or damaged. The roll with no protruding areas and non-protruding areas in the width direction may easily allow tension control for winding under a tension applied uniformly in the width direction of the roll.

In one aspect, the preparing the laminate of the printing substrate film and the masking film may include punching the masking film yet to have the plurality of through-holes to form the plurality of through-holes, and bonding the punched masking film to the surface of the printing substrate film.

In the above structure, the masking film 2 alone is punched, thus simplifying the process and reducing the number of components.

In one aspect, the preparing the laminate of the printing substrate film and the masking film may include bonding the masking film yet to have the plurality of through-holes to a surface of a punching substrate film being elongated and comprising resin to form a laminate of the punching substrate film and the masking film, punching through the laminate of the punching substrate film and the masking film to form the plurality of through-holes, bonding the punched laminate to the surface of the printing substrate film with the punching substrate film being outward, and peeling off the punching substrate film.

In the above structure, the masking film bonded to the punching substrate film is a thicker punch target. The masking film is thus less likely to deform in punching or while being transported to be bonded to the printing substrate film, allowing accurate formation of the through-holes.

In one aspect, the printing substrate film may be a punching-printing substrate film usable in punching the masking film. The preparing the laminate of the printing substrate film and the masking film may include bonding the masking film yet to have the plurality of through-holes to a surface of the punching-printing substrate film to form a laminate of the punching-printing substrate film and the masking film being elongated and comprising resin, and punching the masking film in the laminate of the punching-printing substrate film and the masking film to form the plurality of through-holes.

The pattern-printed thick film roll obtained with this method includes the printing substrate film that is the punching-printing substrate film. The punching-printing substrate film is usable in punching the masking film alone in the laminate of the punching-printing substrate film and the masking film.

In the above structure, the masking film bonded to the punching-printing substrate film is also a thicker punch target. The masking film is thus also less likely to deform in the processes from punching to printing, allowing accurate formation of the through-holes. Additionally, the punching-printing substrate film functions as both the printing substrate film and the punching substrate film, thus simplifying the process and reducing the number of components.

In one aspect, the masking film may be bonded to the printing substrate film in a releasable manner.

In the above structure, the masking film is peeled off and allows downstream processes to be performed after unwinding the roll.

In one aspect, the method according to one or more aspects of the present invention may further include covering, before winding the stack into the roll, the masking film and the pattern-printed thick film layer with a transfer target substrate film to form the stack. The pattern-printed thick film layer may be transferrable from the printing substrate film to the transfer target substrate film.

The pattern-printed thick film roll obtained with this method includes the masking film and the pattern-printed thick film layer covered with an unprintable film. The pattern-printed thick film layer is transferrable from the printing substrate film to the unprintable film.

In the above structure, the pattern-printed thick film layer can be transferred from the printing substrate film to the unprintable film that is suitable for downstream processes after unwinding the roll, although the unprintable film is unsuitable as a substrate on which the pattern-printed thick film layer is printed. The transfer target substrate film may be, for example, a forming substrate film suitable to be formed in a three-dimensional shape or an expanding substrate film suitable to be expanded for use.

In one aspect, the method according to one or more aspects of the present invention may further include covering, before winding the stack into the roll, the masking film and the pattern-printed thick film layer with a protective film to form the stack. The protective film may be releasable from the pattern-printed thick film layer.

The pattern-printed thick film roll obtained with this method includes the masking film and the pattern-printed thick film layer covered with the protective film releasable from the pattern-printed thick film layer.

With the roll including the protective film in the structure described above, the stack has higher surface flatness. The structure protects the pattern-printed thick film layer against damage.

The pattern-printed thick film layer described above may be conductive. The pattern-printed thick film layer may also dissipate heat. The pattern-printed thick film layer may further be adhesive.

### Advantageous Effects

The pattern-printed thick film roll and the method for manufacturing the pattern-printed thick film roll according to the above aspects of the present invention can reduce defective products and material loss.

### BRIEF DESCRIPTION OF DRAWINGS

FIGS. 1A to 1C are views of an example process of printing with a method for manufacturing a pattern-printed thick film roll according to a first embodiment, and FIG. 1D is a view of an example process of winding with the method.

FIGS. 2A and 2B are views of an example process after unwinding the pattern-printed thick film roll according to the first embodiment.

FIGS. 3A and 3B are views of an example punching process with the method for manufacturing the pattern-printed thick film roll according to the first embodiment.

FIGS. 4A to 4D are views of an example punching process with a method for manufacturing a pattern-printed thick film roll according to a second embodiment.

FIGS. 5A to 5C are views of an example punching process with a method for manufacturing a pattern-printed thick film roll according to a third embodiment.

FIG. 6A is a view of an example pattern-printed thick film roll before being wound with a method for manufacturing the pattern-printed thick film roll according to a fourth embodiment, and FIG. 6B is a view of the pattern-printed thick film roll being wound with the method.

FIGS. 7A and 7B are views of an example process after unwinding the pattern-printed thick film roll according to the fourth embodiment.

FIGS. 8A to 8C are views of an example process after unwinding the pattern-printed thick film roll according to the fourth embodiment.

FIG. 9A is a view of an example pattern-printed thick film roll before being wound with a method for manufacturing the pattern-printed thick film roll according to a fifth embodiment, and FIG. 9B is a view of the pattern-printed thick film roll being wound with the method.

FIGS. 10A and 10B are views of an example process after unwinding the pattern-printed thick film roll according to the fifth embodiment.

FIGS. 11A and 11B are views of an example process after unwinding the pattern-printed thick film roll according to the fifth embodiment.

FIG. 12A is a view of an example pattern-printed thick film roll before being wound with a method for manufacturing the pattern-printed thick film roll according to a sixth embodiment, and FIG. 12B is the pattern-printed thick film roll being wound with the method.

FIGS. 13A and 13B are views of an example process after unwinding the pattern-printed thick film roll according to the sixth embodiment.

FIG. 14 is a view illustrating a known screen printing.

### DETAILED DESCRIPTION

A pattern-printed thick film roll and a method for manufacturing the pattern-printed

thick film roll according to one or more embodiments of the present invention are described in detail based on the embodiments shown in the drawings.

### First Embodiment

### (1) Method for Manufacturing Pattern-Printed Thick Film Roll 5

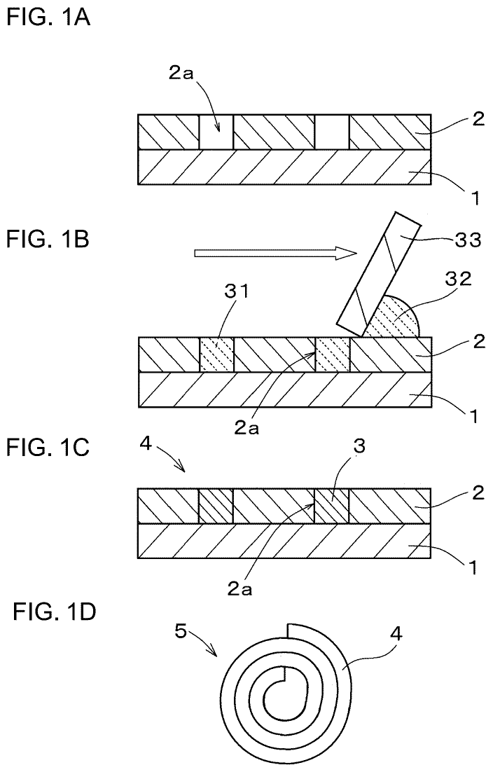

FIGS. 1A to 1C are views of an example process of printing with a method for manufacturing a pattern-printed thick film roll according to a first embodiment of the present invention. FIG. 1D is a view of an example process of winding with the method. FIGS. 1A to 1C are cross-sectional views.

The method for manufacturing a pattern-printed thick film roll according to the first embodiment first includes, as shown in FIG. 1A, preparing a laminate of an elongated resin printing substrate film 1 and an elongated resin masking film 2. The masking film 2 is attached to a surface of the printing substrate film 1. The masking film 2 has multiple through-holes 2a.

The printing substrate film 1 is a resin film having a surface on which a pattern-printed thick film layer 3 (described later) can be printed.

The resin material used for the printing substrate film 1 has high solvent resistance in forming an ink film 31 (described later) and high heat resistance in drying the ink film 31. Examples of the material include polyethylene terephthalate, cycloolefin polymers, polycarbonate, acrylate polymers, polyester, and polyimide.

The printing substrate film 1 may have a thickness of, for example, 10 to 400 μm.

The masking film 2 divides the printing substrate film 1 into portions receiving ink and portions not receiving ink. The masking film 2 covers the printing substrate film 1 other than the through-holes 2a, thus allowing ink to be placed into the through-holes 2a alone on the printing substrate film 1.

Forming the multiple through-holes 2a in the masking film 2 will be described in more detail. As shown in FIGS. 3A and 3B, the masking film 2 yet to have the through-holes 2a is punched to form the through-holes 2a. The through-holes 2a may be formed in any pattern. Such punching typically includes cutting with a die 61 shaped in a plate or a roll. However, the punching may include laser cutting with laser light irradiation.

In an example shown in FIGS. 3A and 3B, the die 61 including a blade 62 having an intended shape is pressed against the masking film 2 from above (refer to FIG. 3A) to punch holes of an intended shape in the masking film 2 (refer to FIG. 3B). The blade 62 in the die 61 punches through the masking film 2 (all cut).

The resin material used for the masking film 2 has high dimensional stability in forming the through-holes 2a, in addition to high solvent resistance in forming the ink film 31 (described later) and high heat resistance in drying the ink film 31. Examples of the material include polyethylene terephthalate, cycloolefin polymers, polycarbonate, acrylate polymers, polyester, and polyimide.

The masking film 2 has a thickness corresponding to the print thickness (wet film thickness) of the ink film (described later). The print thickness (wet film thickness) of the ink film is larger than the thickness (dry film thickness) of a dried pattern-printed thick film layer (described later) to reflect drying shrinkage.

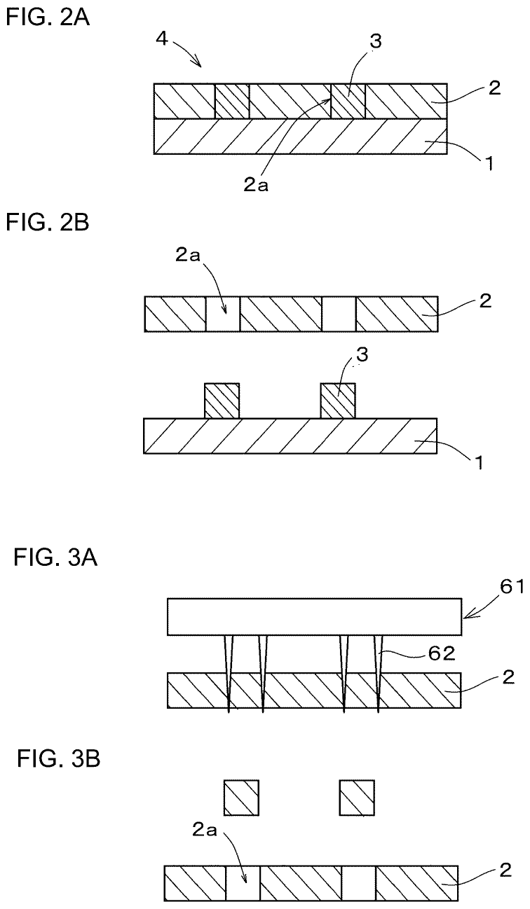

The masking film 2 in the present embodiment is bonded to the printing substrate film 1 in a releasable manner. In other words, an adhesive film (not shown) used for bonding allows the masking film 2 to be easily peelable (refer to FIGS. 2A and 2B). When the masking film 2 is peeled off, the adhesive film may be fully peeled off together with the masking film 2 or may fully remain on the printing substrate film 1.

As shown in FIG. 1B, the through-holes 2a in the masking film 2 in the laminate of the printing substrate film 1 and the masking film 2 are then filled with the ink 32 to form the ink film 31.

More specifically, the laminate is placed on a table. The ink 32 is placed onto the masking film 2. The squeegee 33 in contact with the masking film 2 is horizontally slid to press the ink 32 on the masking film 2 into the through-holes 2a in the masking film 2. This places the ink 32 onto the printing substrate film 1 exposed inside the through-holes 2a (flat printing). As the through-holes 2a are filled with the ink 32, the ink 32 is placed onto the printing substrate film 1. The squeegee 33 passing on the through-holes 2a scrapes the ink 32 to allow the through-holes 2a to receive the ink 32 with the thickness of the masking film 2. The squeegee 33 may be slid twice in the same direction or back and forth to further fill the through-holes 2a with the ink 32.

In some embodiments, filling with the ink may include roll printing in place of the above flat printing. In other words, the laminate of the printing substrate film and the masking film is fed along a rotating roll to be in contact with a fixed squeegee. The ink is placed onto the laminate wound around the rotating roll. The ink on the masking film is then pressed into the through-holes in the masking film with the fixed squeegee. The ink is then placed onto the printing substrate film exposed inside the through-holes.

As shown in FIG. 1C, the ink film 31 is then dried to form the pattern-printed thick film layer 3 having a thickness of 10 to 400 μm.

The drying typically includes blowing hot air. However, the drying may include heating with microwaves instead of blowing hot air. Any other known method may be used for drying.

When the ink undergoing drying shrinkage cannot fully fill the through-holes 2a through one cycle of filling and drying, two or more cycles of filling and drying may be performed.

The pattern-printed thick film layer 3 may function variously. For example, the pattern-printed thick film layer 3 may be conductive. In contrast, the pattern-printed thick film layer 3 may be non-conductive. The pattern-printed thick film layer 3 may also dissipate heat. The pattern-printed thick film layer 3 may further be adhesive. The pattern-printed thick film layer 3 may be conductive or non-conductive, or may dissipate heat as described above in addition to being adhesive. The pattern-printed thick film layer 3 may also have other known characteristics.

The pattern-printed thick film layer 3 having a thickness less than 10 μm cannot have sufficient functions as described above. With the pattern-printed thick film layer 3 having a thickness more than 400 μm, the ink film 31 is more likely to dry and crack. Additionally, the through-holes 2a are more likely to have insufficient filling of ink. The pattern-printed thick film layer 3 may have a thickness of 20 to 200 μm, or more specifically, 30 to 100 μm.

As shown in FIG. 1D, a stack 4 including the printing substrate film 1, the masking film 2, and the pattern-printed thick film layer 3 are finally wound into a roll.

The stack 4 may be wound either with the printing substrate film 1 being outward or with the masking film 2 and the pattern-printed thick film layer 3 being outward.

### (2) Pattern-Printed Thick Film Roll 5

The pattern-printed thick film roll 5 obtained as described above is the stack 4 being wound into a roll. The stack 4 includes the printing substrate film 1, the masking film 2, and the pattern-printed thick film layer 3 (refer to FIG. 1D).

The printing substrate film 1 is an elongated resin film. The masking film 2 is also an elongated resin film. The masking film 2 is bonded to the surface of the printing substrate film 1 in a releasable manner. The masking film 2 has the multiple through-holes 2a. The pattern-printed thick film layer 3 having a thickness of 10 to 400 μm fills the through-holes 2a in the masking film 2.

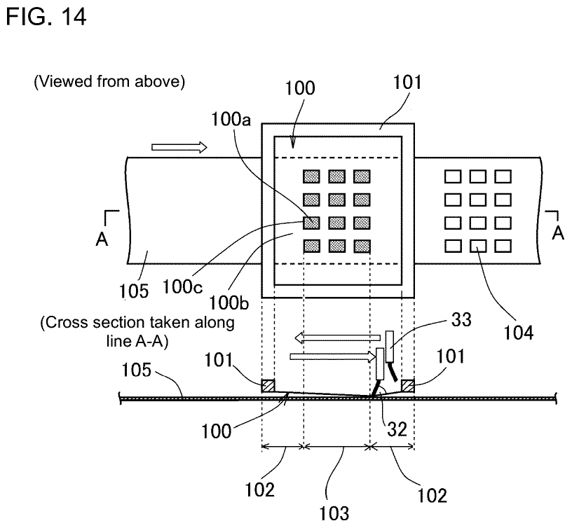

In this structure, the masking film 2 (used in place of a known screen plate) and the printing substrate film 1 have no gaps between them in forming the pattern-printed thick film layer 3, thus allowing the pattern-printed thick film layer 3 with less blotting or less misalignment of the ink. The printing substrate film 1 and the masking film 2 may receive shrinkage stress generated in drying the ink film 31. However, the ink film 31 in the through-holes 2a in the masking film 2 reduces shrinkage of the substrate. Additionally, the masking film 2, unlike the screen plate 100 (refer to FIG. 14), includes no frame 101, thus forming no unprintable area 102 and reducing material loss.

Winding is performed with the masking film 2 having the through-holes 2a filled with the pattern-printed thick film layer 3. This forms no protruding areas including the pattern-printed thick film layer 3 and non-protruding areas including no pattern-printed thick film layer 3. Thus, the shapes of the protruding areas with the pattern-printed thick film layer 3 avoid being transferred to the overlaid printing substrate film 1 being wound. In other words, the shapes do not remain on the overlaid printing substrate film 1. The protruding areas with the pattern-printed thick film layer 3 receive no shear force. The pattern-printed thick film layer 3 can thus avoid being peeled off or damaged. The roll with no protruding areas and non-protruding areas in the width direction may easily allow tension control for winding under a tension applied uniformly in the width direction of the roll.

### Second Embodiment

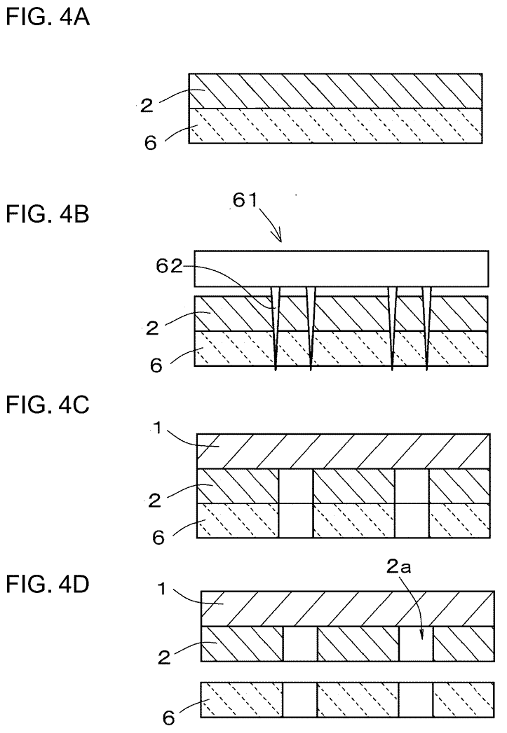

A pattern-printed thick film roll and a method for manufacturing the pattern-printed thick film roll according to a second embodiment of the present invention will now be described with reference to FIGS. 4A to 4D. FIGS. 4A to 4D are cross-sectional views.

In the second embodiment, the process of preparing a laminate of a printing substrate film 1 and a masking film 2 differs from the process in the first embodiment as described below.

More specifically, as shown in FIG. 4A, the masking film 2 yet to have through-holes 2a is bonded to a surface of an elongated resin punching substrate film 6.

The punching substrate film 6 is a resin film that is stacked on the masking film 2 to improve the dimensional stability of the masking film 2. The punching substrate film 6 may be used particularly for a thin masking film 2 used with a thin pattern-printed thick film layer 3.

Examples of the resin material used for the punching substrate film 6 include polyethylene terephthalate, cycloolefin polymers, polycarbonate, acrylate polymers, polyester, and polyimide.

The punching substrate film 6 may have a thickness of, for example, 25 to 200 μm.

The punching substrate film 6 in the present embodiment is bonded to the masking film 2 in a releasable manner. In other words, an adhesive film (not shown) used for bonding allows the punching substrate film 6 to be easily peelable. When the punching substrate film 6 is peeled off, the adhesive film may be fully peeled off together with the punching substrate film 6 or may fully remain on the masking film 2.

As shown in FIG. 4B, the laminate of the punching substrate film 6 and the masking film 2 is punched through to form multiple through-holes 2a.

As shown in FIG. 4C, the punched laminate is then bonded to a surface of the printing substrate film 1 with the punching substrate film 6 being outward.

As shown in FIG. 4D, the punching substrate film 6 is finally peeled off.

A pattern-printed thick film roll 5 obtained with this method is, as in the first embodiment, a stack 4 being wound into a roll. The stack 4 includes the printing substrate film 1, the masking film 2, and the pattern-printed thick film layer 3.

The other structures are the same as those in the first embodiment and are not described repeatedly.

In this structure, the masking film 2 bonded to the punching substrate film 6 is a thicker punch target. The masking film 2 is thus less likely to deform in punching or while being transported to be bonded to the printing substrate film 1, allowing accurate formation of the through-holes.

### Third Embodiment

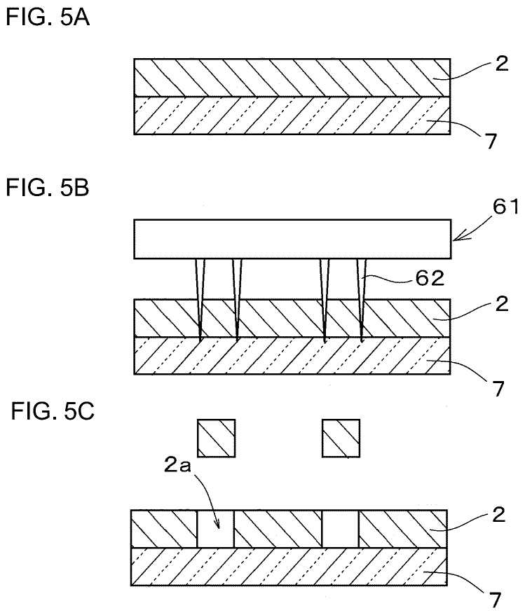

A pattern-printed thick film roll and a method for manufacturing the pattern-printed thick film roll according to a third embodiment will now be described with reference to FIGS. 5A to 5D. FIGS. 5A to 5C are cross-sectional views.

In the third embodiment, the printing substrate film 1 described above is a punching-printing substrate film 7 to be also used in punching a masking film 2, and the process of preparing a laminate differs from the above process of preparing the laminate of the printing substrate film 1 and the masking film 2 in the first embodiment as described below.

More specifically, as shown in FIG. 5A, the elongated resin masking film 2 yet to have through-holes 2a is bonded to a surface of the punching-printing substrate film 7.

The punching-printing substrate film 7 is a resin film that functions as both the printing substrate film and the punching substrate film.

The resin material used for the punching-printing substrate film 7 improves the dimensional stability of the masking film 2 in forming through-holes 2a, in addition to having high solvent resistance in forming an ink film 31 and high heat resistance in drying the ink film 31. Examples of the material include polyethylene terephthalate, cycloolefin polymers, polycarbonate, acrylate polymers, polyester, and polyimide.

The punching-printing substrate film 7 may have a thickness of, for example, 50 to 200 μm.

As shown in FIGS. 5B and 5C, the masking film 2 alone in the laminate of the punching-printing substrate film 7 and the masking film 2 is then punched (half cut) to form the multiple through-holes 2a.

A pattern-printed thick film roll 5 obtained with this method is a stack 4 being wound into a roll. The stack 4 includes the punching-printing substrate film 7, the masking film 2, and a pattern-printed thick film layer 3. Differently from the first embodiment, the punching-printing substrate film 7 is used in place of the printing substrate film 1.

The other structures are the same as those in the first embodiment and are not described repeatedly.

In this structure, the masking film 2 bonded to the punching-printing substrate film 7 is a thicker punch target. The masking film is thus less likely to deform in the processes from punching to printing, allowing accurate formation of the through-holes. Additionally, the punching-printing substrate film functions as both the printing substrate film and the punching substrate film, thus simplifying the process and reducing the number of components.

### Fourth Embodiment

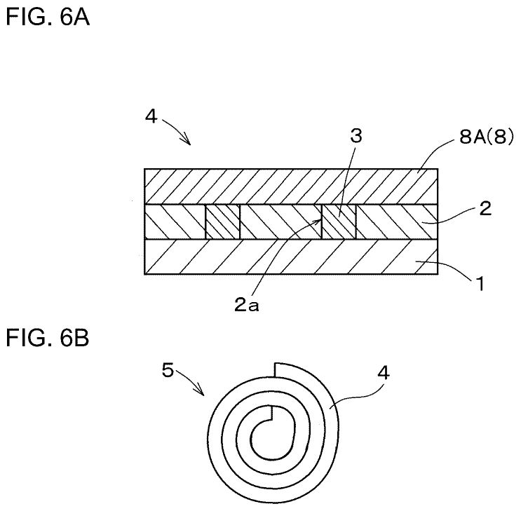

A pattern-printed thick film roll and a method for manufacturing the pattern-printed thick film roll according to a fourth embodiment of the present invention will now be described with reference to FIGS. 6A and 6B. FIG. 6A is a partial cross-sectional view.

In the fourth embodiment, before winding a stack 4 into a roll as described above, a masking film 2 and a pattern-printed thick film layer 3 are covered with a forming substrate film 8A (an example transfer target substrate film 8) to form the stack 4 (refer to FIG. 6A). The pattern-printed thick film layer 3 is transferrable from a printing substrate film 1 to the forming substrate film 8A.

A pattern-printed thick film roll 5 obtained with this method is, as in the first embodiment, the stack 4 being wound into a roll. The stack 4 includes the printing substrate film 1, the masking film 2, and the pattern-printed thick film layer 3 (refer to FIG. 6B). In the present embodiment, the stack 4 further includes the forming substrate film 8A. The forming substrate film 8A covers the masking film 2 and the pattern-printed thick film layer 3.

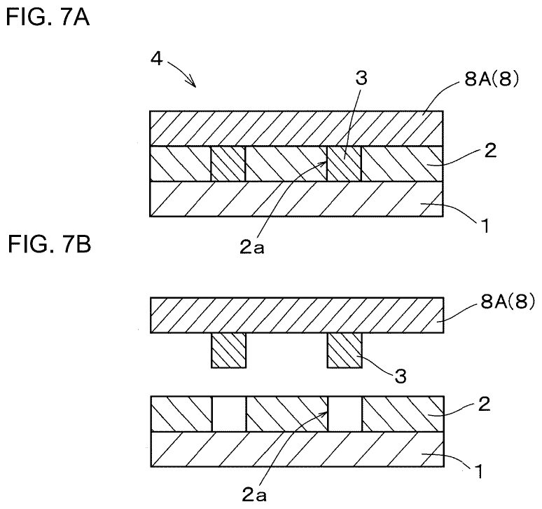

The forming substrate film 8A is bonded to the masking film 2 in a releasable manner. The pattern-printed thick film layer 3 is bonded with higher adhesion to the forming substrate film 8A than to the printing substrate film 1. In other words, when the pattern-printed thick film roll 5 of the stack 4 (refer to FIG. 7A) is unwound again to peel off the masking film 2 from the forming substrate film 8A, the pattern-printed thick film layer 3 remains on the forming substrate film 8A (refer to FIG. 7B).

The layers in the stack 4 are bonded together with the respective adhesive films (not shown) each with an adhesive strength adjusted appropriately. When the masking film 2 is peeled off from the forming substrate film 8A, the adhesive film between the masking film 2 and the forming substrate film 8A may be fully peeled off together with the masking film 2 or may fully remain on the forming substrate film 8A.

The forming substrate film 8A is a resin film that is suitable for a process of forming (an example downstream process) after unwinding the roll, although the forming substrate film 8A is unsuitable as a substrate on which the pattern-printed thick film layer 3 is printed.

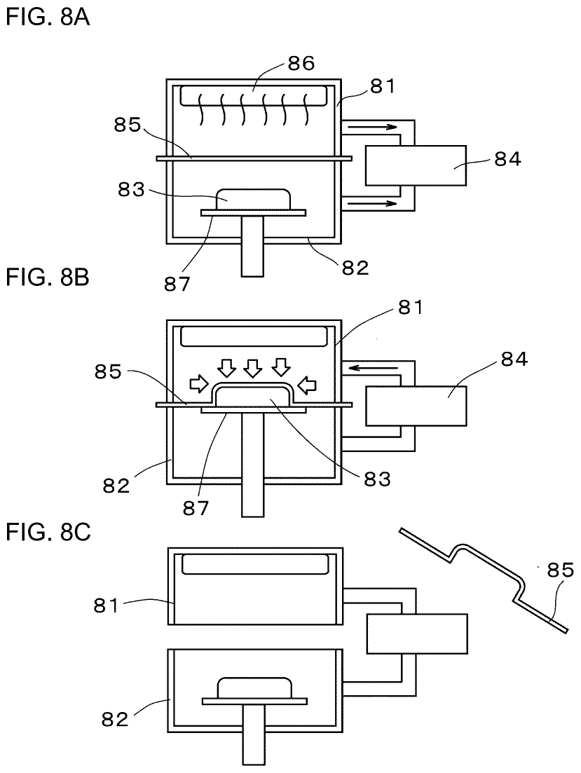

In the process of forming, for example, the forming substrate film 8A with the pattern-printed thick film layer 3 being transferred (hereafter referred to as a forming target material 85) is heated and softened (refer to FIG. 8A). The forming target material 85 is then pressed relative to a three-dimensional tool 83 to be shaped in conformance with the tool 83 (refer to FIG. 8B). After cooling, the resulting forming target material 85 is removed from the tool 83 (refer to FIG. 8C). The forming may further include vacuum forming or pressure forming in addition to heat forming.

The example shown in FIGS. 8A to 8C will be described in more detail below. As shown in FIG. 8A, the forming target material 85 is held between an upper chamber 81 and a lower chamber 82. The upper chamber 81 with a space defined with the forming target material 85 and the lower chamber 82 with a space defined with the forming target material 85 are then evacuated with a vacuum pump 84. At this time, the forming target material 85 is heated and softened with an infrared (IR) heater 86 located in the upper chamber 81.

As shown in FIG. 8B, a lift table 87 located below the forming target material 85 in the lower chamber 82 and holding the tool 83 is raised. The tool 83 is then pressed against the heated and softened forming target material 85, and simultaneously, air is pumped into, with the vacuum pump 84, the space above the forming target material 85 in the upper chamber 81 to press the heated and softened forming target material 85 against the tool 83.

The resin material used for the forming substrate film 8A has high thermoformability. Examples of the resin material include polyethylene, polyvinyl alcohol, polymethyl methacrylate, and acrylonitrile butadiene styrene (ABS).

The forming substrate film 8A has a thickness of 10 to 400 μm.

The other structures are the same as those in the first embodiment and are not described repeatedly.

In this structure, the pattern-printed thick film layer 3 can be transferred from the printing substrate film 1 to the forming substrate film 8A that is suitable for the process of forming after unwinding the roll, although the forming substrate film 8A is unsuitable as a substrate on which the pattern-printed thick film layer 3 is printed.

### Fifth Embodiment

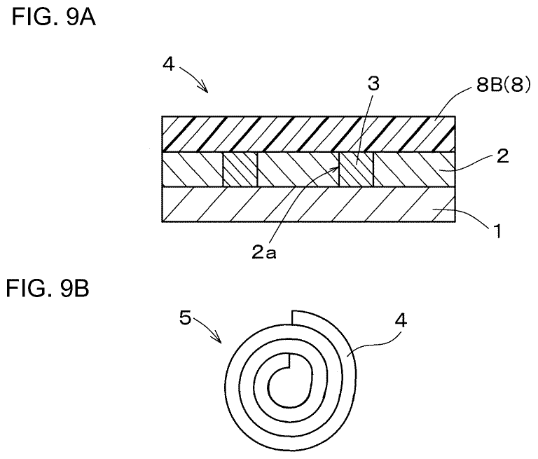

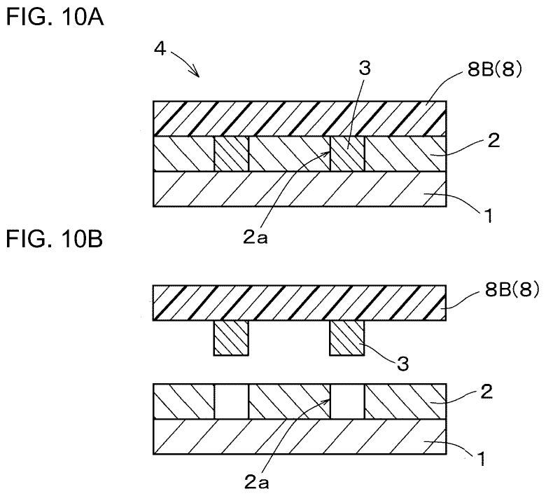

A pattern-printed thick film roll and a method for manufacturing the pattern-printed thick film roll according to a fifth embodiment of the present invention will now be described with reference to FIGS. 9A to 10B.

In the fifth embodiment, before winding a stack 4 into a roll as described above, a masking film 2 and a pattern-printed thick film layer 3 are covered with an expanding substrate film 8B (an example transfer target substrate film 8) to form the stack 4 (refer to FIG. 9A). The pattern-printed thick film layer 3 is transferrable from a printing substrate film 1 to the expanding substrate film 8B.

A pattern-printed thick film roll 5 obtained with this method is, as in the first embodiment, the stack 4 being wound into a roll. The stack 4 includes the printing substrate film 1, the masking film 2, and the pattern-printed thick film layer 3 (refer to FIG. 9B). In the present embodiment, the stack 4 further includes the expanding substrate film 8B. The expanding substrate film 8B covers the masking film 2 and the pattern-printed thick film layer 3.

The expanding substrate film 8B is bonded to the masking film 2 in a releasable manner. The pattern-printed thick film layer 3 is bonded with higher adhesion to the expanding substrate film 8B than to the printing substrate film 1. In other words, when the pattern-printed thick film roll 5 of the stack 4 (refer to FIG. 10A) is unwound again to peel off the masking film 2 from the expanding substrate film 8B, the pattern-printed thick film layer 3 remains on the expanding substrate film 8B (refer to FIG. 10B).

The layers in the stack 4 are bonded together with the respective adhesive films (not shown) each with an adhesive strength adjusted appropriately. When the masking film 2 is peeled off from the expanding substrate film 8B, the adhesive film between the masking film 2 and the expanding substrate film 8B may be fully peeled off together with the masking film 2 or fully remain on the expanding substrate film 8B.

The expanding substrate film 8B is a resin film that is suitable for a process of expanding (an example downstream process) after unwinding the roll, although the expanding substrate film 8B is unsuitable as a substrate on which the pattern-printed thick film layer 3 is printed.

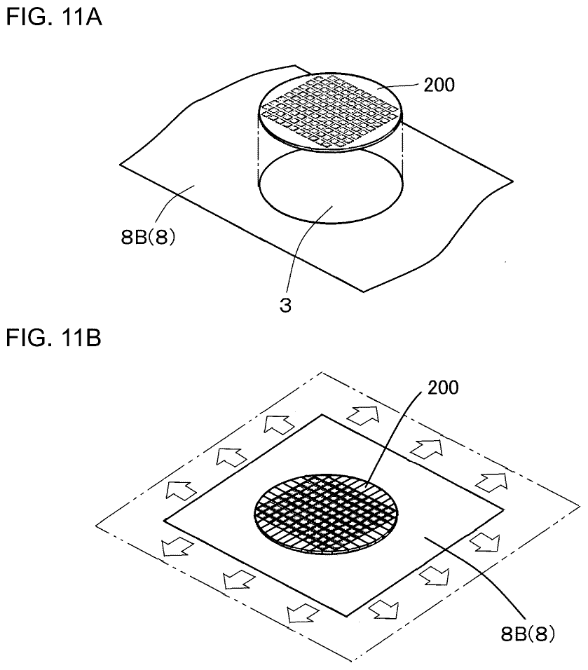

In a typical example process of expanding, a semiconductor wafers 200 attached to the pattern-printed thick film layer 3 on the expanding substrate film 8B (refer to FIG. 11A) is diced into chips. The expanding substrate film 8B holding the diced chips is expanded toward its periphery (refer to FIG. 11B). This increases the distances between the chips and allows, for example, a charge-coupled device (CCD) camera to easily recognize the chips. This also reduces damage in the chips caused by any contact between the chips when the chips are picked up.

The resin material used for the expanding substrate film 8B is highly expandable. Examples of the material include polyethylene, polypropylene, polyvinyl chloride, polyvinylidene chloride, and ethylene-vinyl acetate copolymer.

The expanding substrate film 8B may have a thickness of 10 to 400 μm.

The other structures are the same as those in the first embodiment and are not described repeatedly.

In this structure, the pattern-printed thick film layer 3 can be transferred from the printing substrate film 1 to the expanding substrate film 8B that is suitable for the process of expanding after unwinding the roll, although the expanding substrate film 8B is unsuitable as a substrate on which the pattern-printed thick film layer 3 is printed.

### Sixth Embodiment

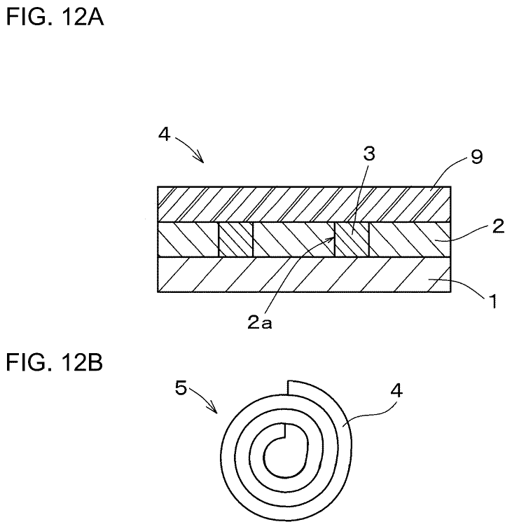

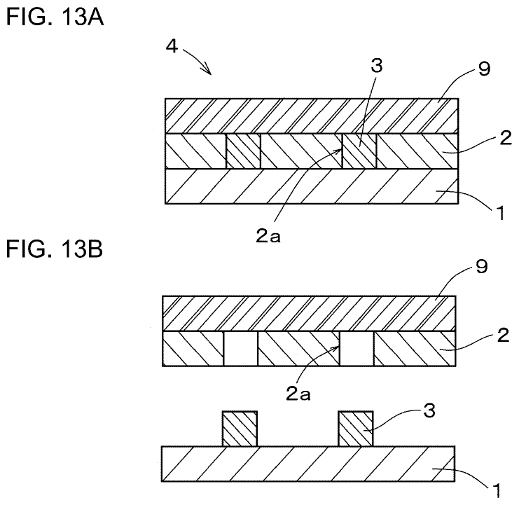

A pattern-printed thick film roll and a method for manufacturing the pattern-printed thick film roll according to a sixth embodiment of the present invention will now be described with reference to FIGS. 12A to 13B.

In the sixth embodiment, before winding a stack 4 into a roll as described above, a masking film 2 and a pattern-printed thick film layer 3 are covered with a protective film 9, which is releasable from the pattern-printed thick film layer 3, to form the stack 4 (refer to FIGS. 12A and 12B).

A pattern-printed thick film roll 5 obtained with this method is, as in the first embodiment, the stack 4 being wound into a roll. The stack 4 includes a printing substrate film 1, the masking film 2, and the pattern-printed thick film layer 3. In the present embodiment, the stack 4 further includes the releasable protective film 9. The protective film 9 covers the masking film 2 and the pattern-printed thick film layer 3.

The protective film 9 is bonded to at least the pattern-printed thick film layer 3 in a releasable manner (refer to FIGS. 13A and 13B).

The layers in the stack 4 are bonded together with the respective adhesive films (not shown) each with an adhesive strength adjusted appropriately. When the masking film 2 integral with the protective film 9 is peeled off, the adhesive film between the pattern-printed thick film layer 3 and the protective film 9 may be fully peeled off together with the protective film 9 or may fully remain on the pattern-printed thick film layer 3. The protective film 9 and the masking film 2 may be peeled off in separate processes.

The resin material used for the protective film 9 has high scratch resistance and high abrasion resistance. Examples of the material include polyethylene terephthalate, cycloolefin polymers, polycarbonate, acrylate polymers, polyester, polyimide, polyethylene, polystyrene, and polyvinyl alcohol.

The protective film 9 may have a thickness of, for example, 25 to 200 μm.

The other structures are the same as those in the first embodiment and are not described repeatedly.

In this structure, the stack 4 has higher surface flatness. This structure protects the pattern-printed thick film layer 3 against damage.

Although the embodiments of the present invention have been described, the present invention is not limited to the embodiments, and may be changed in various manners without departing from the spirit and scope of the present invention. The embodiments and modifications described herein can be combined in any manner as appropriate.

### REFERENCE SIGNS LIST

1 printing substrate film
2 masking film
2a through-hole
3 pattern-printed thick film layer
31 ink film
32 ink
33 squeegee
4 stack
5 pattern-printed thick film roll
6 punching substrate film
61 die
62 blade
7 punching-printing substrate film
8 transfer target substrate film
8A forming substrate film
8B expanding substrate film
81 upper chamber
82 lower chamber
83 tool
84 vacuum pump
85 forming target material
86 IR heater
87 lift table
9 protective film
100 screen plate
100a screen mesh
100b emulsion
100c opening
101 frame
102 unprintable area
103 printable area
104 print pattern
105 substrate film
200 semiconductor wafer

1. A method for manufacturing a pattern-printed thick film roll, the method comprising:
preparing a laminate of a printing substrate film and a masking film, the printing substrate film being elongated and comprising resin, the masking film being elongated and comprising resin, the masking film having a plurality of through-holes and being bonded to a surface of the printing substrate film;
filling, with ink, the plurality of through-holes in the masking film in the laminate of the printing substrate film and the masking film to form an ink film;
drying the ink film to form a pattern-printed thick film layer having a thickness of 10 to 400 μm; and
winding a stack including the printing substrate film, the masking film, and the pattern-printed thick film layer into a roll.

2. The method according to claim 1, wherein
the preparing the laminate of the printing substrate film and the masking film includes
punching the masking film yet to have the plurality of through-holes to form the plurality of through-holes, and
bonding the punched masking film to the surface of the printing substrate film.

3. The method according to claim 1, wherein
the preparing the laminate of the printing substrate film and the masking film includes
bonding the masking film yet to have the plurality of through-holes to a surface of a punching substrate film to form a laminate of the punching substrate film and the masking film, the punching substrate film being elongated and comprising resin,
punching through the laminate of the punching substrate film and the masking film to form the plurality of through-holes,
bonding the punched laminate to the surface of the printing substrate film with the punching substrate film being outward, and
peeling off the punching substrate film.

4. The method according to claim 1, wherein
the printing substrate film is a punching-printing substrate film usable in punching the masking film, and
the preparing the laminate of the printing substrate film and the masking film includes
bonding the masking film yet to have the plurality of through-holes to a surface of the punching-printing substrate film to form a laminate of the punching-printing substrate film and the masking film, the masking film being elongated and comprising resin, and
punching the masking film in the laminate of the punching-printing substrate film and the masking film to form the plurality of through-holes.

5. The method according to any one of claims 1 to 4, wherein
the masking film is bonded to the printing substrate film in a releasable manner.

6. The method according to any one of claims 1 to 4, further comprising:
covering, before winding the stack into the roll, the masking film and the pattern-printed thick film layer with a transfer target substrate film to form the stack, the pattern-printed thick film layer being transferrable from the printing substrate film to the transfer target substrate film.

7. The method according to claim 6, wherein
the transfer target substrate film is a forming substrate film.

8. The method according to claim 6, wherein
the transfer target substrate film is an expanding substrate film.

9. The method according to any one of claims 1 to 5, further comprising:
covering, before winding the stack into the roll, the masking film and the pattern-printed thick film layer with a protective film to form the stack, the protective film being releasable from the pattern-printed thick film layer.

10. The method according to any one of claims 1 to 9, wherein
the pattern-printed thick film layer is conductive.

11. The method according to any one of claims 1 to 9, wherein
the pattern-printed thick film layer dissipates heat.

12. The method according to any one of claims 1 to 11, wherein
the pattern-printed thick film layer is adhesive.

13. A pattern-printed thick film roll, comprising:
a stack being wound into a roll, the stack including
a printing substrate film being elongated and comprising resin,
a masking film being elongated and comprising resin, the masking film having a plurality of through-holes and being bonded to a surface of the printing substrate film, and
a pattern-printed thick film layer filling the plurality of through-holes in the masking film, the pattern-printed thick film layer having a thickness of 10 to 400 μm.

14. The pattern-printed thick film roll according to claim 13, wherein
the printing substrate film is a punching-printing substrate film, and the punching-printing substrate film is usable in punching the masking film in a laminate of the punching-printing substrate film and the masking film.

15. The pattern-printed thick film roll according to claim 13 or claim 14, wherein
the masking film is bonded to the printing substrate film in a releasable manner.

16. The pattern-printed thick film roll according to any one of claims 13 to 15, wherein
the masking film and the pattern-printed thick film layer are covered with a transfer target substrate film, and the pattern-printed thick film layer is transferable from the printing substrate film to the transfer target substrate film.

17. The pattern-printed thick film roll according to any one of claims 13 to 15, wherein
the masking film and the pattern-printed thick film layer are covered with a protective film releasable from the pattern-printed thick film layer.
